(19) United States
(12) Patent Application Publication
(10) Pub. No.: US 2011/0175207 A1
(43) Pub. Date: Jul. 21, 2011

(54) METHOD FOR PRODUCING METAL OXIDE LAYERS

(75) Inventors: Hanno Schnars, Stadland-Rodenkirchen (DE); Mathias Wickleder, Hichenbach (DE); Katharina Al-Shamery, Bad Zwischenahn (DE)

(73) Assignee: CARL VON OSSIETZKY UNIVERSITÄT OLDENBURG, Oldenburg (DE)

(21) Appl. No.: 13/000,809

(22) PCT Filed: Jun. 23, 2009
(86) PCT No.: PCT/EP2009/057855

§ 371 Date: Mar. 18, 2011

(30) Foreign Application Priority Data
Jun. 23, 2008 (DE) DE102008029385.7

(51) Int. Cl. H01L 23/58; H01L 21/473; B05C 13/02; B05C 11/00; B05C 11/11; B05C 3/02; B05B 17/00

(52) U.S. Cl. 257/632; 438/758; 118/66; 118/73; 257/E21.494; 257/E23.002

(57) ABSTRACT

The invention relates to a method for producing metal oxide layers from oxides of rare earth metals on silicon-containing surfaces, to the device used to carry out the coating method, and to the use of the starting materials used in the method according to the invention for the coating method.

The invention relates to a method for producing metal oxide layers, in particular from oxides of the rare earth metals, on surfaces containing silicon, to the device used for performing the coating method, and to the use of the starting materials used in the method according to the invention for the coating method

Surfaces containing silicon that are provided with an oxide layer of rare earth metals using the coating method according to the invention are in particular surfaces of silicon dioxide, for example glass, borosilicate glass, quartz glass, and other glass compositions that consist essentially of silicon dioxide, in particular surfaces of pure silicon, preferably hydrogen-terminated silicon or OH-terminated silicon, monocrystalline or polycrystalline in each case.

The rare earth metal oxide layers obtained using the coating method on silicon-containing surfaces, in particular on pure silicon, are suitable as protective layers due to their mechanical properties, and, due to their high dielectric constant, which is present even in a thin layer, are suitable as a dielectric intermediate layer of electrical semiconductor elements, in particular in a MOSFET or in a DRAM.

It is known to provide field-effect transistors (MOST ET) with a gate insulator made of silicon dioxide, which is applied as a dielectric onto a surface of pure silicon. However, for an effective insulation silicon dioxide used as dielectric layer requires a minimum layer thickness; below that thicknesses leakage currents occur due to quantum-mechanical tunnel effect. This minimum thickness of a silicon dioxide insulating layer sets a lower limit for the miniaturization of MOSFETs.

DE 3744368 C1 describes a method for producing rare earth oxide layers on glass surfaces by heating of partially hydrolyzed oxides using laser radiation applied in solution. The only example for a precursor substance of an oxide layer is tetraethoxy titanium for the production of a titanium dioxide layer on glass.

WO 99/02756 describes the production of a metal oxide layer in semiconductor components by application of metallic alkoxides by means of atomizing a solution in a vacuum, followed by heating of the deposited metallic alkoxy compounds.

DE 69307533 T2 describes the production of metal oxide layers by applying a metal alkoxycarboxylate in solution, followed by heating.

EP 1659130 A1 describes the production of rare earth metal oxide layers by chemical deposition from the gas phase (CVD method) ,wherein a complex of the rare earth metal with sec-butylcyclopentadiene as a ligand is applied as precursor substance, and is subsequently decomposed by heating to the rare earth oxide.

US 2003/0072882 A1 describes a CVD coating method for producing thin rare earth oxide layers by applying cyclopentadienyl compounds of the rare earth metals, followed by thermal decomposition.

U.S. Pat. No. 5,318,800 describes a method for producing a metal oxide coating by applying a polymer-metal-complex precursor compound, with subsequent burning off for the removal of the polymer and for the oxidation of the metal.

EP 1617467 A1 describes the coating of a silicon surface with a metal oxide for the production of an insulating thin film.

GB 776,443 describes the production of refractory oxide layers on metal by applying metal carbonates or metal nitrates; the coating of silicon, which is itself not refractory, is not mentioned.

The known coating methods for producing a rare earth oxide layer on silicon-containing surfaces have the disadvantage that the metal-organic compounds for the use in CVD methods volatalize only with difficulty, resulting in the incorporation of carbon atoms in the oxide layer, which impairs its electrical properties and/or stability.

### OBJECT OF THE INVENTION

Against the background of the known methods, the object of the present invention is to provide an alternative method for producing rare earth oxide layers on silicon-containing surfaces, in particular on surfaces of glass or pure silicon, the method enabling in particular a simple process controlling.

### General Description of the Invention

The invention achieves the above-named object by the features indicated in the claims, and in particular by a method for producing rare earth oxide layers on silicon-containing surfaces, in particular on glass or pure silicon, in particular hydrogen-terminated silicon, in which as a precursor at least one rare earth nitrate or a transition metal nitrate having the general formula Mⁿ(NO₃)ₙ, optionally as hydrate in solution, for example in aqueous and/or alcoholic solution, is applied onto the surface that is to be coated, and the rare earth oxide layer and/or transition metal oxide layer is produced through decomposition of the rare earth metal nitrate or transition metal nitrate through thermal treatment, in particular after removal of the solvent. For the purposes of the invention, the metal nitrate of one or more metals, which is preferably a rare earth nitrate, comprises as rare earth (M in Mⁿ(NO₃)ₙ) at least one of the group comprising the metals lanthanum, Sc, Y, Ce, Pr, Nd, Pm, Sm, Eu, Gd, Tb, Dy, Ho, Er, Tin, Yb, Ln, Hf, Tb, Lu, Ti, Zr, V, Nb, Ta, Cr, Mo, W, Mn, Re, Fe, Ru, Os, Co, Rh, Ir, Ni, Pd, Pt, Cu, Ag, Au, Zn, Cd, Hg, Ga, In, TI, Ge, Sn, and Pb, preferably one from the group of the rare earth metals, which comprises lanthanum, Sc, Y, Ce, Pr, Nd, Pm, Sm, Eu, Gd, Tb, Dy, Ho, Er, Tm, Yb, Ln, and Hf, more preferably La, Sc, Y, Pr, Nd, Eu, Dy, Er, and/or Hf, and mixtures of the afore-mentioned, e.g. mixtures of two or more of the above-named metal nitrates. Preferred mixtures are Dy with Sc, or Sm with Sc. Correspondingly, reference hereinafter to the rare earths or rare earth metals also comprises the above-mentioned groups of metals, including the transition metals, and the term rare earth oxides and rare earth metal oxides also comprises the oxides of the above-mentioned groups, including the transition metal oxides, as well as mixtures thereof.

It has turned out that mixtures of two or more metal nitrates, or mixed metal nitrates, in the method according to the invention result in a mixed metal oxide layer that contains the metal oxides in intimate mixture. The metals can be present in mixtures of their nitrates in quantity portions of, in each case, 0.01 to 0.99 relative to the other metals of the mixture.

Particularly preferably, the mixture of at least two metal nitrates is a polynary nitrate having the formula M×M′y(NO₃)_{3(x+y)} and solvates thereof M×M′y(NO₃)_{3(x+y)}xl., wherein M and M′ are different rare earth metals and/or transition metals, and are preferably each rare earth metals, in particular Sm in combination with Sc, or Dy in combination with Sc, and L is a solvation ligand as described hereinafter. Preferred values for x and y, respectively independently of one another, are whole numbers, e.g. each from 1 to 100, preferably each from 1 to 10. If there are three or more metals, M′ is replaced by two or more metals, and its index y is replaced by a portion in the compound allocated to each metal. It has turned out that in such polynary rare earth oxide metal nitrates and/or transition metal nitrates, the two or more metals are contained in a common compound, or in the same compound respectively, and are contained in a common crystal structure. The oxide layers produced by the method according to the invention from such polynary nitrates or nitrate solvates exhibit a very homogenous distribution of the metals contained therein. Mixed metal oxide layers produced in this way have significantly fewer defect points, and have a higher homogeneity of the distribution of the metals, as well as a particularly small layer thickness, e.g. a maximum of 10 nm.

Correspondingly, the present invention also relates to the metal oxide layers or metal mixed oxide layers produced by the described method on a silicon-containing surface.

Particularly preferred, the metal nitrate is a rare earth metal nitrate having the general formula M(NO₃)₃·xL, wherein L is a ligand, in particular a non-metallic ligand, or solvation ligand, embedded in the crystal lattice of the rare earth metal nitrate in the quantity x, e.g. H₂O for hydrates of the metal nitrates, in which x is for example 3 to 6. L may further be selected from C1 to C6 alkyl compounds, in particular C1 to C6 alcohol, in particular methanol (MeOH), ethanol, n-propanol, isopropanol, butanol (BuOH), in particular n-butanol or isobutanol, tetrahydrofuran (THF), methylcyano groups (MeCN), or dimethoxyethane (DME). The compounds M(NO₃)₃ xL used in the method according to the invention, which are also referred to as solvates of the metal nitrates, can be obtained by contacting the pure rare earth metal nitrate or transition metal nitrate with the solvent that contains or consists of the solvation ligand.

Particularly preferred metal nitrates are La(NO₃)(H₂O)₆, Pr(NO₃)₃(H₂O)₆, Nd(NO₃)₃(H₂O)₆, La(NO₃)(DME)₂, La(NO₃)(THF)₄, Pr(NO₃)₃(THF)₃, Nd(NO₃)₃(THF)₃, Sc(NO₃)₃(THF)₃, La(NO₃)₃(MeOH)_{5.25}, Pr(NO₃)₃(MeOH)₅, Nd(NO₃)₃(MeOH)_{3.5}, La(NO₃)₃(THF)₃, La(NO₃)₃(MeCN)_{5/3}, Pr(NO₃)₃(MeCN)_{8/3}, Nd(NO₃)₃(MeCN)_{3.5}, Sm(NO₃)₃(THF)₃. La(NO₃)₃(BuOH)₂, Nd(NO₃)₃(BuOH)₂, and Sm/Sc (NO₃)₃(THF)₃, wherein Sm and Sc are present in 1:1 mixture.

The application of the solution of the rare earth metal nitrate can be accomplished using conventional methods, for example immersion, coating with a doctor knife, deposition of droplets from an aerosol or liquid jet (for example ink-jet printing) of the solution of the rare earth metal nitrate, for example in a vacuum, in particular in ultrahigh vacuum, in protective gas atmosphere or in air. Preferably, solvent, for example water and/or alcohol, is removed from the rare earth metal nitrate solution by evaporation, preferably under reduced pressure and/or increased temperature, followed by a thermal treatment, in particular to approximately 500 to 700° C., preferably approximately 650° C., which results in the production of a rare earth oxide layer.

Advantageously, the rare earth metal nitrates used according to the invention are chemically stable, i.e. they are not subject to undesirable decomposition at normal storage temperatures, and are commercially available.

In addition, the rare earth metal nitrates used as precursor substances of the rare earth oxide layer are free of carbon and free of chlorine, so that, if necessary after the removal of organic solvent, the incorporation of carbon or chlorine into the oxide layer is avoided, and a rare earth oxide layer having a reduced content, or no content, of carbon and/or chlorine is obtainable.

Furthermore, the invention provides a device for producing a rare earth metal oxide layer on a silicon-containing surface, and the use of such a device for performing the method according to the invention respectively. The device usable according to the invention in the method for production of a rare earth metal oxide layer on a silicon-containing surface, which has a device for applying a precursor substance, which precursor substance upon thermal decomposition forms a rare earth oxide layer, is characterized in that the application device comprises a device for applying a solution that comprises the rare earth nitrate used according to the present invention. Such a device for applying a solution can be a device for surface wetting of the silicon-containing surface, for example a device for immersion of the silicon-containing surface into the solution, or a doctor knife device for applying the solution, a device for depositing droplets of the solution, the droplets being produced for example by atomization of the solution or by spraying, e.g. through a nozzle, and being deposited on the silicon-containing surface.

For the decomposition of the rare earth nitrate to a rare earth oxide on the silicon-containing surface, the device according to the invention contains a heating device, for example an oven and/or an irradiation device, particularly preferred a laser that is to be directed onto the silicon-containing surface.

The method according to the invention preferably serves for the production of semiconductor components that have a rare earth oxide layer on a silicon-containing surface, in particular on a silicon surface, and/or for production of glass having a rare earth oxide layer.

Preferably, the silicon-containing surface, for example of a silicon-containing substrate, for example of glass or of pure silicon, is pre-treated prior to the application of the solution with a content of rare earth nitrate for the production of a defined surface of the substrate. A preferred pre-treatment of the silicon-containing surface can comprise the treatment in an ultrasonic bath, in particular with acetone or some other solvent for dissolving lipophilic contaminants.

For silicon-containing surfaces, in particular of pure silicon, an oxidation is preferred, for example by boiling in a mixture of sulfuric acid and hydrogen peroxide (3:1) in order to produce a defined silicon dioxide layer on the silicon-containing surface, preferably followed by a removal of the silicon dioxide layer, for example by etching in hydrofluoric acid, for example by contacting the silicon-containing surface with HF (1 to 10%) at room temperature.

Particularly preferred, the silicon-containing surface, especially when the surface consists of pure silicon, is converted to a hydrogen-terminated surface, for example through treatment with aqueous 40% NFU solution with further addition of an aqueous 35% (NH₄)₂SO₃ solution in a 15:1 ratio in a nitrogen stream.

Between the individual treatment steps of the pre-treatment, the silicon-containing surface is preferably rinsed with super-clean water after the production of a hydrogen-terminated surface this rinsing is very brief, e.g. for a maximum of 10 s, so that no new oxide layer will be produced.

Particularly preferred, the pre-treatment of the silicon-containing surface takes place in a vacuum or in a protective gas atmosphere.

Corresponding to the method steps for pre-treating the silicon-containing surface, according to the invention the solution of at least one rare earth nitrate is applied to a surface that has or that consists of silicon dioxide, preferably to a silicon surface that is hydrogen-terminated and/or hydroxy-group-terminated.

The method according to the invention is suitable in particular for the use for layers having an essentially uniform layer thickness of less than 250 nm, preferably less than 100 to 150 nm, in particular approximately a maximum of 50 to a maximum of 150 nm, particularly preferably a maximum of 10 nm. The production of uniform layer thicknesses using the method according to the invention in the production of optical elements, in particular for the production of optically transparent dielectric layers, is suitable in particular for use in the production of field-effect transistors, in particular MOSFETs, LEDs, and also OLEDs and solar cells.

The device for heating the silicon-containing surface coated with rare earth nitrate, for example an oven or a laser, is preferably capable of being evacuated so that the thermal decomposition of the rare earth nitrate to the rare earth oxide on the silicon-containing surface can take place preferably without the incorporation of foreign atoms. As an alternative or in addition to the vacuum present in the heating device, a protective gas atmosphere can be provided.

As alternative to the wet-chemical pre-treatment of the silicon-containing surface, in particular for surfaces of pure silicon, the pre-treatment can be of brief heating of the silicon-containing surface to at least 1000° C., preferably at least 1250° C., and a controlled cooling can be provided with a cooling rate of approximately 0.2 to 0.3 K/s, preferably approximately 0.25 K/s.

Particularly preferably, the silicon-containing surface, in particular a surface of pure silicon in a vacuum, in particular a vacuum of a maximum of 2×10⁻⁹ mbar (absolute), is degassed at approximately 700° C.

### DETAILED DESCRIPTION OF THE INVENTION

The present invention is now described in more detail by way of examples with reference to the Figures, in which

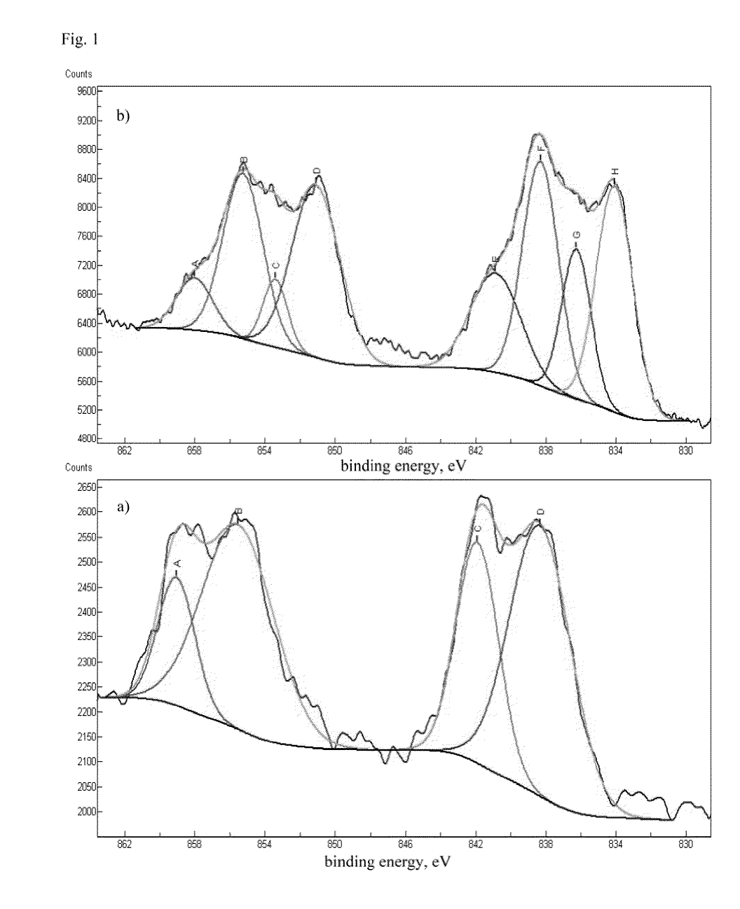

FIG. 1 shows the measurement results of the X-ray photoelectron spectroscopy (XPS) of a silicon surface, namely a) after the coating with lanthanum nitrate before the thermal decomposition, and b) of the same surface after thermal decomposition;

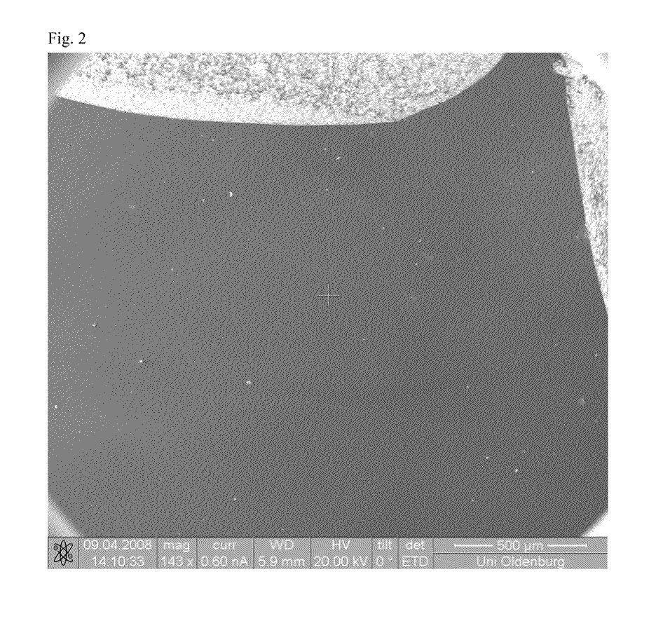

FIG. 2 shows a scanning electron microscopic image of a lanthanum oxide layer produced according to the invention on a silicon surface;

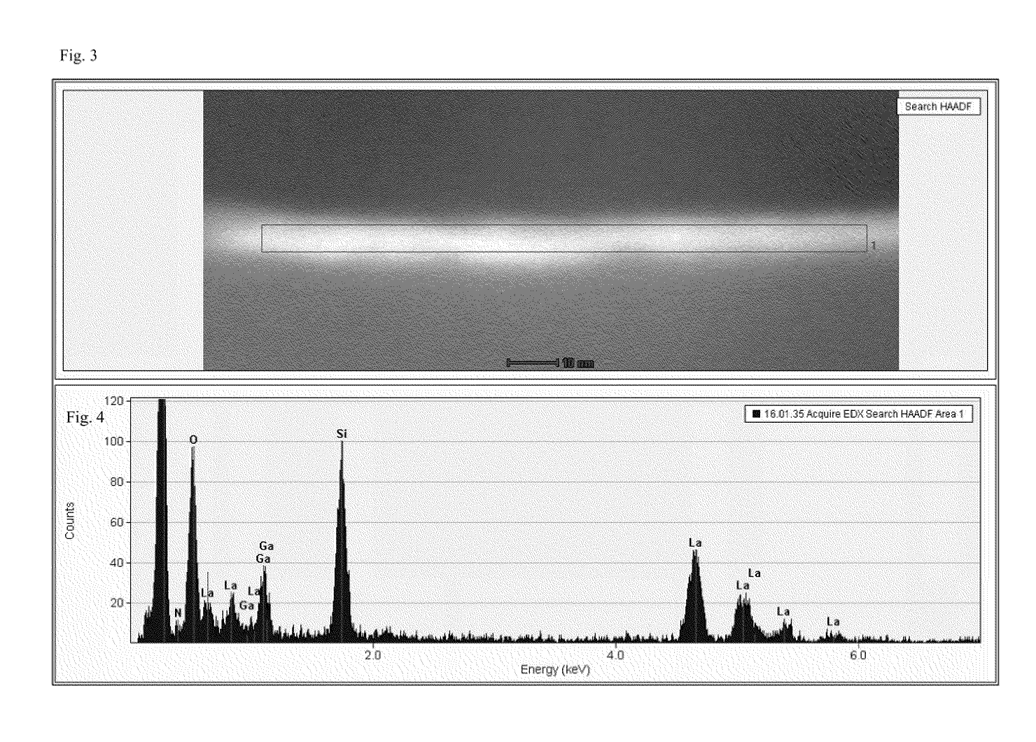

FIG. 3 shows a transmission electron microscopic image of a cross-section perpendicular through a lanthanum oxide layer produced according to the invention on a silicon surface;

FIG. 4 shows the result of an energy-dispersive X-ray spectroscopy using X-ray beam excitation, and

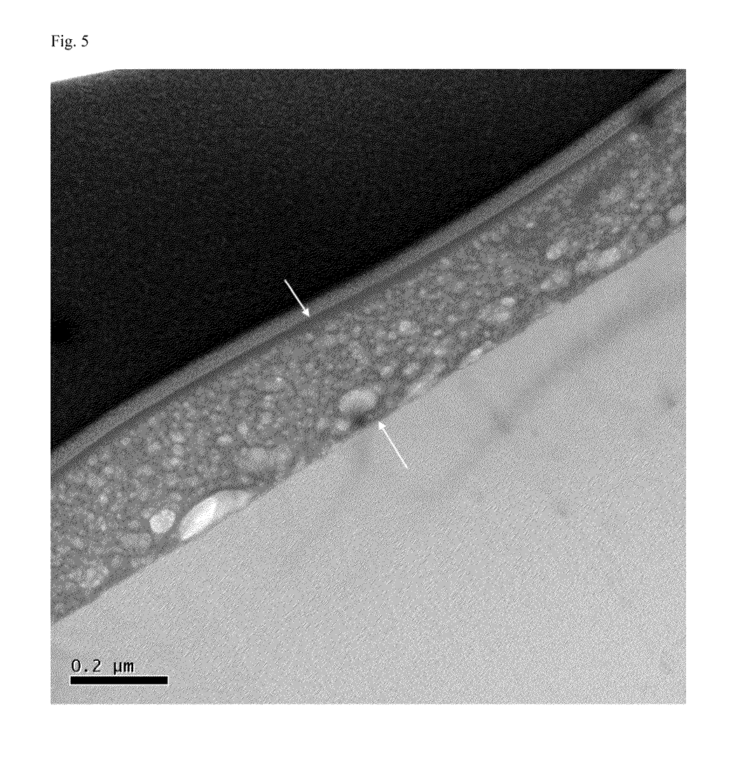

FIG. 5 shows a transmission electron microscopic image of another sample of a lanthanum oxide layer on silicon, produced according to the invention.

Advantageously, the production of metal oxide layers can take place by heating to the following temperatures; wherein optionally the indication of the number of steps describes the conversion reaction of the nitrate to the oxide:

La(NO₃)(H₂O)₆ in 3 steps, end of the reaction at 600° C.,

Pr(NO₃)₃(H₂O)₆ in 3 steps, end of the reaction at 475° C.,

Nd(NO₃)₃(H₂O)₆ in 3 steps, end of the reaction at 660° C.,

La(NO₃)(DME)₂ in 3 steps, end of the reaction at 580° C. with an exothermic step at 225° C.,

Pr(NO₃)₃(THF)₃ in 3 steps, end of the reaction at 430° C. with an exothermic step at 220° C.,

Nd(NO₃)₃(THF)₃ in 3 steps, end of the reaction at 660° C. with an exothermic step at 185° C.,

La(NO₃)₃(MeOH)_{5.25} in 3 steps, end of the reaction at 590° C. with an exothermic step at 280° C.,

Pr(NO₃)₃(MeOH)₅ in 3 steps, end of the reaction at 460° C. with an exothermic step at 270° C.,

Nd(NO₃)₃(MeOH)_{3.5} in 3 steps, end of the reaction at 680° C. with an exothermic step at 270° C.,

La(NO₃)₃(MeCN)_{5/3} in 3 steps, end of the reaction at 590° C. with an exothermic step at 180° C.,

Pr(NO₃)₃(MeCN)_{8/3} in 3 steps, end of the reaction at 500° C. with an exothermic step at 170° C.,

Nd(NO₃)₃(MeCN)_{3.5} in 3 steps, end of the reaction at 640° C. with an exothermic step at 160° C.,

Sm(NO₃)₃(THF)₃ in 3 steps, end of the reaction at 600° C. with an exothermic step at 140° C.,

La(NO₃)₃(BuOH)₂ in 3 steps, end of the reaction at 600° C. with an exothermic step at 270° C.,

Nd(NO₃)₃(BuOH)₂ in 3 steps, end of the reaction at 650° C. with an exothermic step at 200° C.,

Sm/Sc (NO₃)₃(THF)₃, wherein Sm and Sc are present in 1:1 mixture, in 3 steps, end of the reaction at 650° C. with exothermic step at 100° C. for the mixed oxide.

### EXAMPLE 1

Rare Earth Oxide Layer on Silicon

For the method of production according to the invention for a rare earth oxide layer on a silicon-containing surface, an alcoholic lanthanum nitrate solution was applied to a pre-treated surface of pure silicon, and was converted by heating to a lanthanum oxide layer fixed firmly to the silicon surface.

The substrate of pure silicon was first treated in an ultrasonic bath and washed with acetone, subsequently boiled in 3:1 sulfuric acid/H₂O₂ in order to obtain a defined oxide layer. The oxide layer on the substrate of pure silicon was removed by immersing the sample in 5% HF at room temperature. For the production of an oxide-free silicon surface which was hydrogen-terminated, the substrate was treated with 40% NH₄F solution with further addition of a 35% (NH₄)₂SO₃ solution in the ratio of 15:1 in a nitrogen stream, each time with brief rinsing of the substrate with distilled water for a maximum of 10 seconds.

The substrate prepared in this way was placed into an ultrahigh vacuum chamber.

The solution having the rare earth nitrate, in the present example lanthanum nitrate, could be prepared in water, or for the wetting of the silicon surface could preferably be prepared in a C₁-C₆ alcohol, particularly preferably in 2-propanol and/or butanol. In order to apply the lanthanum nitrate over the complete surface, the silicon surface was immersed in the solution of the lanthanum nitrate and then, removed.

The heating took place in an ultrahigh vacuum, to 650° C. at 0.5 K/s. The final temperature was maintained for approximately 60 seconds, cooling subsequently took place to room temperature. Gaseous decomposition products released during the heating were determined as nitrogen oxides, using a mass spectrometer connected to the vacuum chamber.

After drying for removal of the solvent, but prior to the thermal decomposition of the lanthanum nitrate, the substrate of silicon coated with lanthanum nitrate was analyzed using X-ray photoelectron spectroscopy, and after the heating for thermal decomposition. The results are shown in FIG. 1, namely a) prior to the thermal decomposition of the lanthanum nitrate and b) after the thermal decomposition of the lanthanum nitrate. Comparison of the spectra shows that the doublet for the La3d peak value, which splits to form a doublet of La3d 3/2 and La3d 5/2, has shifted due to the heating, indicating the conversion of the rare earth nitrate to the rare earth oxide for the example of lanthanum oxide.

FIG. 2 shows a scanning electron microscope image of the silicon surface provided with the lanthanum oxide layer. Here it becomes clear that the applied rare earth oxide layer has been produced as essentially uniform and flat, without any particular roughness.

Energy-dispersive X-ray spectroscopy confirmed that lanthanum is uniformly distributed within the lanthanum oxide layer.

For determination of the layer thickness and morphology of the rare earth oxide layer on the silicon surface, transmission electron microscopic images were made of cross-sections of the silicon substrate and of the rare earth oxide layer situated thereon. The transmission electron microscopy was carried out on lamellae cut from the sample of the rare earth oxide-coated silicon using an ion beam, handled under an optical microscope using mechanical micromanipulators.

FIG. 3 shows a segment of the transmission electron microscopic image, namely showing as the center bright strip approximately in the center of the image, the lanthanum oxide layer, above the carbon layer (not inventive) that stems .from the preparation for the electron microscopy, and the pure silicon of the substrate underneath the lanthanum oxide layer. The layer thickness of the lanthanum oxide was determined as approximately 10 nm, which is joined to the silicon surface directly without detectable gaps.

The layer thickness of approximately 10 nm for the lanthanum oxide layer was confirmed in initial analyses using angle-dependent XPS (X-ray photoelectron spectroscopy).

FIG. 4 shows the result of the energy-dispersive X-ray spectroscopy and confirms the composition of the rare earth oxide layer as lanthanum oxide; the detection of carbon and platinum is the result of contaminants stemming from the carbon or platinum coating for the electron microscopy, the detection of gallium results from the focused gallium ion beam used to produce the lamellar segment from the substrate.

The dielectric constant of a rare earth oxide layer on silicon produced in this way has values suitable for the production of integrated circuits, for example MOSFETs.

### EXAMPLE 2

### Production of a Lanthanum Oxide Layer on Silicon

Corresponding to Example 1, silicon having a lanthanum oxide layer was produced by thermal decomposition Of lanthanum nitrate applied from solution on a hydrogen-terminated silicon substrate.

Corresponding to Example 1 a lamella was cut approximately perpendicular to the plane of the surface of the silicon substrate, from the silicon coated with lanthanum oxide using a focused ion beam and was analyzed using transmission electron microscopy:

FIG. 5 shows the layer of lanthanum oxide produced on the silicon substrate shown at the lower right of the image; the thickness of the lanthanum oxide layer is indicated by the two inserted arrows. The layer thickness was estimated as approximately 300 to 350 nm. This example shows that the layer of lanthanum oxide has irregularities, which are presumably enclosed gaseous decomposition products of the rare earth nitrate. By changing the process parameters, in particular the concentration of rare earth nitrate in the solution, the rate of heating and cooling, as well as the vacuum, thinner layers of rare earth oxide could be produced on a substrate, which furthermore were homogenous, e.g. did not have gas enclosures.

Therefore, the examples show that using the method of the invention metal oxide layers, in particular rare earth oxide layers, can be produced that are essentially homogenous or that are porous, e.g. having hollow spaces that may be produced by gas enclosures in the rare earth oxide layer. Preferably, the rare earth oxide layers have a closed surface situated opposite their surface adjoining the substrate.

1. Method for the production of rare earth metal oxide layers on a silicon-containing surface by applying a precursor compound of a metal oxide onto the silicon-containing surface, followed by thermal decomposition of the precursor compound, wherein the precursor compound contains a metal nitrate or a metal nitrate complex compound having an organic ligand or water.

2. Method according to claim I ,wherein the metal nitrate is applied in solution.

3. Method according to claim I, wherein the solution is an aqueous solution and/or an alcoholic solution with saturated C₁ to C₆ alcohol.

4. Method according to claim 1, wherein the metal nitrate has the formula Mⁿ(NO₃)ₙ·.xL wherein L is an organic ligand or water, and M is at least one member of the group comprising lanthanum, Sc, Y, Ce, Pr, Nd, Pm, Sm, Eu, Gd, Tb, Dy, Ho, Er, Tin, Yb, Ln, HI, Tb, Lu, Ti, Zr, V, Nb. Ta, Cr, Mo, W, Mn, Re, Fe, Ru, Os, Co, Rh, Ir, Ni, Pd, Pt, Cu, Ag. Au, Zn, Cd, Hg, Ga, In, TI, Ge, Sn and Pb.

5. Method according to claim 1, wherein the organic ligand is selected from the group comprising C1 to C6 alkyl compounds, C1 to C6 alcohols, tetrahydrofuran (THF), methylcyano groups (MeCN), and dimethoxyethane (DME).

6. Method according to claim I, wherein the metal nitrate is a mixture of at least two rare earth metal nitrates or a polynary rare earth metal nitrate having at least two rare earth metals, and the metal oxide is a rare earth metal mixed oxide.

7. Method according to claim I, wherein the metal nitrate has a mixture of at least two transition metal nitrates or has a polynary transition metal nitrate that has at least two transition metals, and the metal oxide is a metal mixed oxide.

8. Method according to claim 1, wherein the thermal decomposition comprises a heating to a temperature of at least 500° C., at least 650° C., or at least 700° C.

9. Method according to claim 1, wherein the thermal decomposition comprises heating using irradiation.

10. Method according to claim 9, wherein the irradiation is laser radiation.

11. Method according to claim 1, wherein the application of the metal nitrate and/or the thermal decomposition takes place in a vacuum and/or under protective gas atmosphere.

12. Method according to claim 1, wherein the silicon-containing surface comprises silicon dioxide, hydrogen-terminated silicon and/or OH-terminated silicon, or consists of silicon.

13. Method according to claim 1, wherein the silicon-containing surface is pre-treated by oxidation and subsequent reduction.

14. Method according to claim 1, wherein the silicon-containing surface is pre-treated by heating to approximately 1250° C. and cooling at a maximum rate of 0.2 K/s in an ultrahigh vacuum.

15. Method according to claim 1, having the step of processing the produced metal oxide layer to a field effect transistor.

16. Silicon-containing surface having a metal oxide layer, obtainable through a method according to claim 1.

17. Device for use in the production of metal oxide layers on silicon-containing surfaces according to claim 1, having a device for applying a solution of a precursor substance of the metal oxide layer that forms a metal oxide layer upon thermal decomposition, wherein the device for applying a solution comprises a device for applying a solution having a content of metal nitrate.

18. Device according to claim 17, wherein the device for applying a solution is an immersion bath for immersing the silicon-containing surface.

19. Device according to claim 1, wherein the device has a device for pre-treatment of the silicon-containing surface, equipped for heating to a temperature of approximately at least 1250° C. and cooling at a maximum rate of approximately 0.2 K/s.

20. Device according to claim 17, wherein the device for applying the solution has a pulsed spray device.

21. Device according to claim 17, wherein the metal nitrate is a rare earth metal nitrate or a transition metal nitrate.

22. Use of a metal nitrate having the formula Mⁿ(NO₃)ₙ·xL, wherein L is water of crystallization or an organic ligand, and M is at least one member of the group that comprises lanthanum, Sc, Y, Ce, Pr, Nd, Pm, Sm, Eu, Gd, Tb, Dy, Ho, Er, Tm, Yb, Ln, Elf, Tb, Lu, Ti, Zr, V, Nb, Ta, Cr, Mo, W, Mn, Re, Fe, Ru, Os, Co, Rh, Ir, Ni, Pd, Pt, Cu, Ag, Au, Zn, Cd, Hg, Ga, In, TI, Ge, Sn, and Pb, in a method according to claim 1.
